(19) United States
(12) Patent Application Publication
(10) Pub. No.: US 2008/0179625 A1
(43) Pub. Date: Jul. 31, 2008

(54) CMOS image sensor having transistor with conduction band offset

(76) Inventors: Kyung-Ho Lee, Suwon-Si (KR); Yi-Tae Kim, Hwaseong-Si (KR); Jung-Chak Ahn, Yongin-Si (KR)

Correspondence Address: LAW OFFICE OF MONICA H CHOI, P O BOX 3424, DUBLIN, OH, 430160204, US

(21) Appl. No.: 11/985,016

(22) Filed: Nov. 13, 2007

(30) Foreign Application Priority Data
Jan. 30, 2007 (KR) 2007-09309

(51) Int. Cl. H01L 27/146

(52) U.S. Cl. 257/187; 257/E27.133

(57) ABSTRACT

An image sensor includes a photo sensitive device and at lest one transistor such as a drive transistor for converting charge accumulated by the photo sensitive device into an electrical signal. That at least one transistor includes a channel region comprised of a plurality of differently doped regions that generates a conduction band offset in the channel region. Such a conductive band offset increases electron mobility in the channel region for minimizing charge trapping at an interface between a gate dielectric and the semiconductor substrate for minimizing flicker noise.

This application claims priority under 35 USC § 119 to Korean Patent Application No. 2007-09309, filed on Jan. 30, 2007 in the Korean Intellectual Property Office, the disclosure of which is incorporated herein in its entirety by reference.

### BACKGROUND OF THE INVENTION

1. Field of the Invention

The present invention relates generally to image sensors, and more particularly, to a CMOS (complementary metal oxide semiconductor) image sensor with at least one transistor having a conduction band offset for minimizing flicker noise.

2. Background of the Invention

An image sensor is a semiconductor device which converts an optical image into electrical signals. An image sensor may be a charge coupled device (CCD) or a CMOS (Complementary Metal Oxide Semiconductor) image sensor (CIS). A unit pixel of a CMOS image sensor includes a photo sensitive device (PSD) to accumulate charge from an image. In addition, the unit pixel includes transistors, such as a transfer transistor, a reset transistor, and a drive transistor, for converting the accumulated charge into an electrical signal for a signal processing circuit.

However, the CMOS image sensor having such a structure may have flicker noise due to charge trapping in an interface between silicon (Si) and silicon oxide (SiO₂). Such flicker noise degrades the quality of the reproduced image. Accordingly, a CMOS image sensor with minimized flicker noise is desired.

### SUMMARY OF THE INVENTION

Accordingly, a buried channel with multiple differently doped regions are formed for a transistor of a unit pixel for minimizing flicker noise in a CMOS image sensor.

An image sensor of an aspect of the present invention includes a photo sensitive device and at lest one transistor for converting charge accumulated by the photo sensitive device into an electrical signal. The at least one transistor includes a channel region comprised of a plurality of differently doped regions that generates a conduction band offset in the channel region.

In one embodiment of the present invention, the at least one transistor is a drive transistor having a gate dielectric and a gate electrode formed over the channel region that is buried in a semiconductor substrate.

In another embodiment of the present invention, the image sensor further includes a floating diffusion node, a transfer transistor, a select transistor, and a reset transistor. The floating diffusion node is coupled to a gate of the drive transistor. The transfer transistor is coupled between the photo sensitive device and the floating diffusion node. The select transistor is coupled between the drive transistor and an output node. The reset transistor is coupled between the floating diffusion node and a reset voltage source.

In a further embodiment of the present invention, each of the transfer transistor, the select transistor, and the reset transistor has a respective channel comprised of a plurality of differently doped regions that generates a respective conduction band offset in the respective channel region.

In another embodiment of the present invention, the plurality of differently doped regions further generates a valence band offset in the channel region. For example, the valence band offset is formed at an interface of a silicon substrate and a region comprised of SiGe (silicon germanium).

In a further embodiment of the present invention, the conduction band offset is formed at an interface of a region comprised of SiGe (silicon germanium) and another region comprised of SiGeC (silicon germanium carbon).

In another embodiment of the present invention, the plurality of differently doped regions includes first and second regions of SiGe (silicon germanium) and a region of SiGeC (silicon germanium carbon) formed between the first and second regions of SiGe. In that case, the regions of SiGe and SiGeC are formed buried below a surface of a silicon substrate.

For example, germanium is implanted with a first dopant profile to form the first region of SiGe, and germanium is implanted with a second dopant profile to form a second region of SiGe. Carbon is further implanted with a third dopant profile to form a region of SiGeC. An anneal is performed at a temperature of from about 800 to about 1000° C. after the steps of implanting germanium and carbon.

The present invention may be used to particular advantage when the image sensor is a CMOS (complementary metal oxide semiconductor) image sensor.

In this manner, a heterojunction is formed for generating the conduction band offset in the buried channel region of the drive transistor. Such a buried channel region provides higher conductivity of electrons for reducing flicker noise in the CMOS image sensor.

### BRIEF DESCRIPTION OF THE DRAWINGS

The above and other features and advantages of the present invention will become more apparent when described in detailed exemplary embodiments thereof with reference to the attached drawings in which:

FIG. 1 is a circuit diagram of a unit pixel included in a CMOS image sensor, according to an embodiment of the present invention;

FIG. 2 illustrates a layout of the unit pixel of FIG. 1, according to an embodiment of the present invention;

FIGS. 3A and 3B are cross-sectional views of the unit pixel taken along the line III-III illustrated in FIG. 2, according to an embodiment of the present invention;

FIG. 3C shows energy bands having a conduction band offset and a valence band offset for a channel region in a drive transistor of the unit pixel of FIGS. 1, 2, and 3A, according to an embodiment of the present invention;

FIGS. 4, 5, 6, 7A, 7B, 8, and 9 are cross-sectional views showing fabrication of the unit pixel of FIG. 3A, according to an embodiment of the present invention; and

FIG. 7C shows dopant profiles for forming different regions of a buried channel in the drive transistor of the unit pixel, according to an embodiment of the present invention.

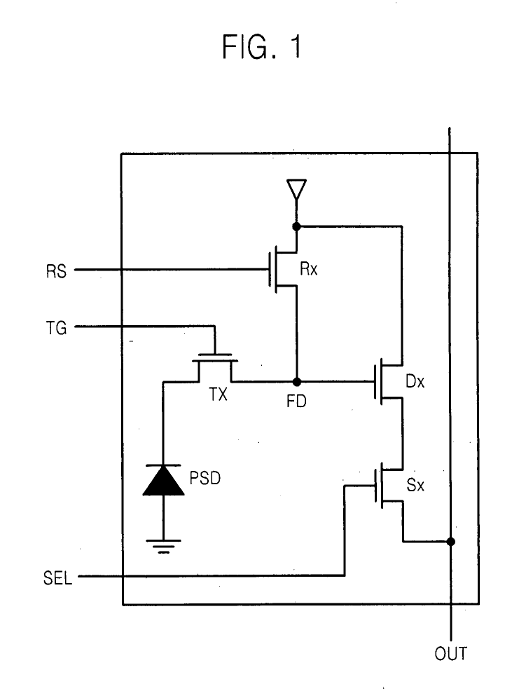

The figures referred to herein are drawn for clarity of illustration and are not necessarily drawn to scale. Elements having the same reference number in FIGS. 1, 2, 3A, 3B, 3C, 4, 5, 6, 7A, 7B, 7C, 8, and 9 refer to elements having similar structure and/or function.

### DETAILED DESCRIPTION OF THE INVENTION

The present invention is now described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first signal could be termed a second signal, and similarly, a second signal could be termed a first signal without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

FIG. 1 is a circuit diagram of a unit pixel included in a CMOS (complementary metal oxide semiconductor) image sensor, according to an embodiment of the present invention. As illustrated in FIG. 1, the unit pixel in the CMOS image sensor includes a photo sensitive device (PSD) that generates charge in response to incident light. The PSD may be implemented as a photo diode, a photo transistor, a photo gate, a pinned photo diode (PPD), or a combination thereof, in an embodiment of the present invention.

In addition, the unit pixel of FIG. 1 includes a transfer transistor Tx for transferring charge generated by the PSD to a floating diffusion region FD. Furthermore, the unit pixel of FIG. 1 has a reset transistor Rx for periodically resetting the potential at the floating diffusion region FD. Also, the unit pixel of FIG. 1 includes a drive transistor Dx configured as a source follower buffer amplifier for generating an electrical signal corresponding to the amount of charge in the floating diffusion region FD. Additionally in FIG. 1, a select transistor Sx performs switching for when the unit pixel is being addressed. In FIG. 1, “RS” refers to a control signal applied on a gate of the reset transistor Rx, and “TG” refers to a control signal applied on a gate of the transfer transistor Tx.

The unit pixel of FIG. 1 includes a single PSD and four MOS transistors Tx, Rx, Dx, and Sx, but the present invention is not restricted thereto. The present invention may be used for any unit pixel having at least three transistors including a transfer transistor and a source follower buffer amplifier and a PSD.

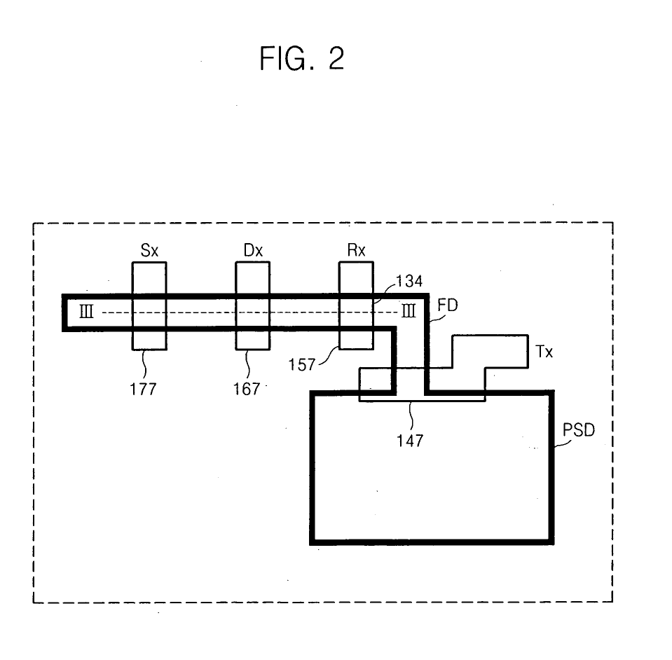

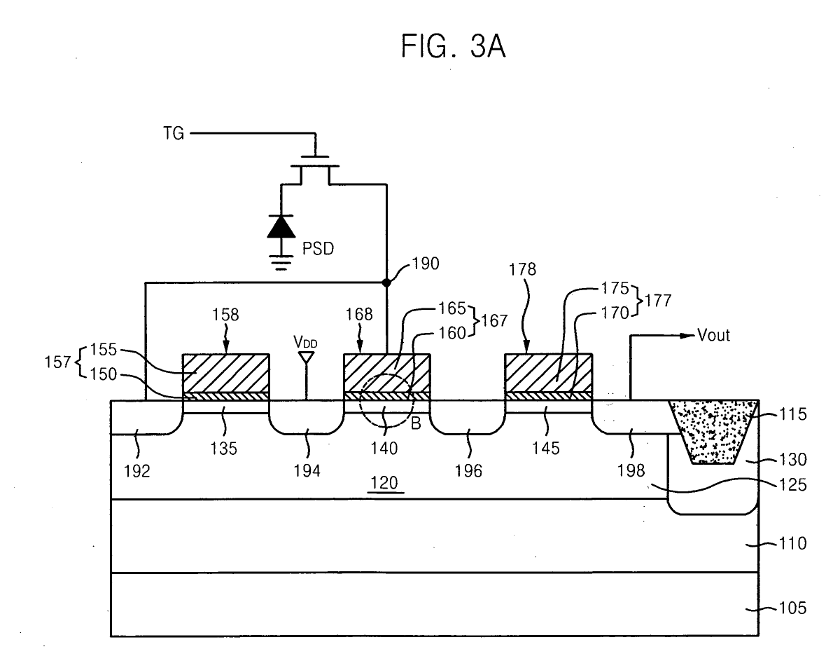

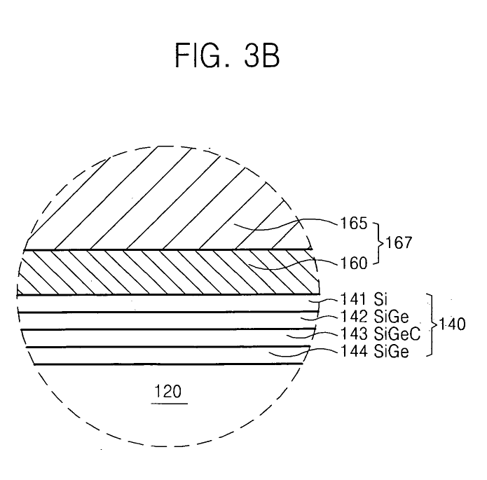

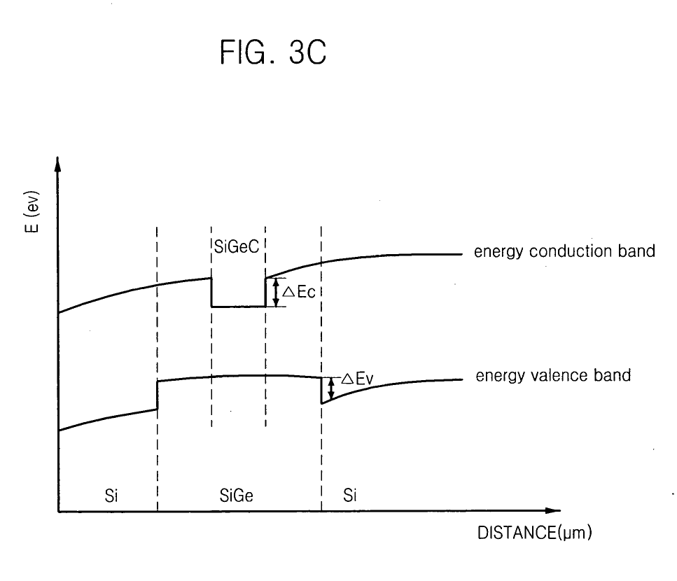

Such unit pixel is now described in more detail with reference to FIGS. 2, 3A, 3B, and 3C. FIG. 2 illustrates a layout of such a unit pixel such as the unit pixel of FIG. 1, according to an embodiment of the present invention. FIGS. 3A and 3B are cross-sectional views of the unit pixel taken along the line III-III of FIG. 2, according to an embodiment of the present invention. FIG. 3C shows a conductive energy band and a valence energy band of a channel region in a drive transistor for the unit pixel.

Referring to FIG. 2, the unit pixel includes an active region 120 (shown outlined by a bold solid line in FIG. 2) and a device isolation region (115 in FIG. 3A) formed outside the active region 120. A gate 147 of the transfer transistor Tx, a gate 157 of the reset transistor Rx, a gate 167 of the drive transistor Dx, and a gate 177 of the select transistor Sx are formed over the active region 120.

FIG. 3A shows a cross-sectional view of the reset transistor (Rx) 158, the drive transistor (Dx) 168, and the select transistor (Sx) 178 formed in a semiconductor substrate 105. The semiconductor substrate 105 is comprised of silicon in one embodiment of the present invention. In an example embodiment of the present invention, the reset transistor 158, the drive transistor 168, and the select transistor 178 are NMOSFETs (N-channel metal oxide semiconductor field effect transistors).

A deep P-well 110 is formed in the semiconductor substrate 105 as a deep conductive path in the active region 120. The device isolation region 115 is surrounded by a channel stop region 130 in one embodiment of the present invention. The channel stop region 130 is a P-type impurity doped region in contact with the deep P-well 110, according to one embodiment of the present invention. The active region 120 on the deep P-well 110 includes a P-well 125 doped with a P-type dopant such as boron (B) or boron fluoride (BF₂) in one embodiment of the present invention.

A drain region 194 of the reset transistor 158 is formed in the active region 120 and is connected to a reset voltage source VDD. A source region 192 of the reset transistor 158 is formed in the active region 120 and is connected to a floating diffusion node (FD) 190. The drive transistor 168 shares the drain region 194 with the reset transistor 158 and shares a source region 196 with the select transistor 178 with such drain and source regions 194 and 196 being formed in the active region 120. A drain region 198 of the select transistor 178 formed in the active region 120 generates an output voltage Vout.

The source and drain regions 192, 196, 194, and 198 have N-type doping in one embodiment of the present invention. The designation of regions 192, 196, 194, and 198 as a source or a drain is for an example embodiment of the present invention only. Such designation may be interchanged for example.

A reset gate 157 comprised of a gate dielectric 150 and a gate electrode 155 are formed over a portion of the active region 120 between the source and drain regions 192 and 194. A drive gate 157 comprised of a gate dielectric 160 and a gate electrode 165 are formed over a portion of the active region 120 between the drain and source regions 194 and 196. A select gate 157 comprised of a gate dielectric 170 and a gate electrode 175 are formed over a portion of the active region 120 between the drain and source regions 196 and 198.

The gate dielectrics 150, 160, and 170 are comprised of a same material such as silicon oxide or silicon nitride for example, in an example embodiment of the present invention. Also, the gate electrodes 155, 165, and 175 are comprised of a same material such as polysilicon, tungsten (W), titanium nitride (TiN), tantalum (Ta), tantalum nitride (TaN), or a combination thereof, in an example embodiment of the present invention. However, the present invention may also be practiced when the gate dielectrics 150, 160, and 170 are comprised of different materials and when the gate electrodes 155, 165, and 175 are comprised of different materials.

At a channel region below the reset gate 157 in the semiconductor substrate 105, a first impurity doped region 135 is formed for controlling a threshold voltage of the reset transistor Rx. At a channel region below the drive gate 167 in the semiconductor substrate 105, a second impurity doped region 140 is formed for controlling a threshold voltage of the drive transistor Dx. At a channel region below the select gate 177 in the semiconductor substrate 105, a third impurity doped region 145 is formed for controlling a threshold voltage of the select transistor Sx.

Each of the first and third impurity doped regions 135 and 145 has a single-layer structure doped with a P-type dopant or alternatively has a stack structure with an additional N-type doped region below the P-type doped region. Referring to FIGS. 3A and 3B, the second impurity doped region 140 includes a plurality of differently doped regions such as a stack structure of a Si (silicon) region 141, then a SiGe (silicon germanium) region 142, then a SiGeC (silicon germanium carbon) region 143, and then a SiGe region 144 formed from the top surface of the silicon substrate 105.

FIG. 3C shows an energy valence band and an energy conduction band for such regions 141, 142, 143, and 144. A valence-band offset of ΔEv which is a discontinuity in the energy valence band exists at a respective heter junction formed at each of the interfaces between a silicon region and a SiGe region. In addition, a band offset of ΔEc which is a discontinuity in the energy conduction band exists at a respective heterojunction formed at each of the interfaces between a SiGe region and a SiGeC region.

With such conduction-band discontinuity ΔEc, negative carriers (i.e., electrons) move in a quantum well. A charge accumulation layer formed near an interface of the SiGeC region 143 becomes a channel through which the electrons move at high speed. With such high speed movement of electrons, the motion of electrons toward a silicon and silicon oxide interface is restricted.

Accordingly, the mobility of electrons is greater in the SiGeC region 143 than in the Si regions 141 and 120 such that the operating speed of the drive transistor 168 is increased. With such increased mobility, charge loss from charge trapping at an interface between the silicon substrate 105 and the gate dielectric 160 comprised of silicon oxide is prevented to reduce flicker noise in the drive transistor 168.

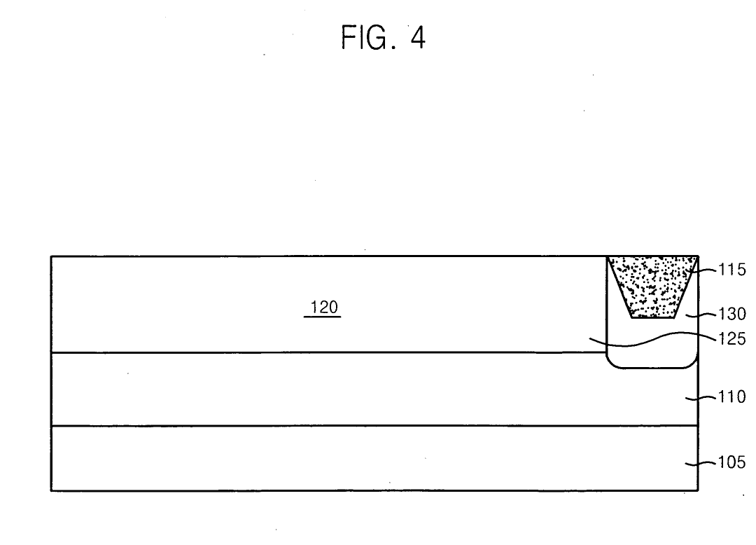

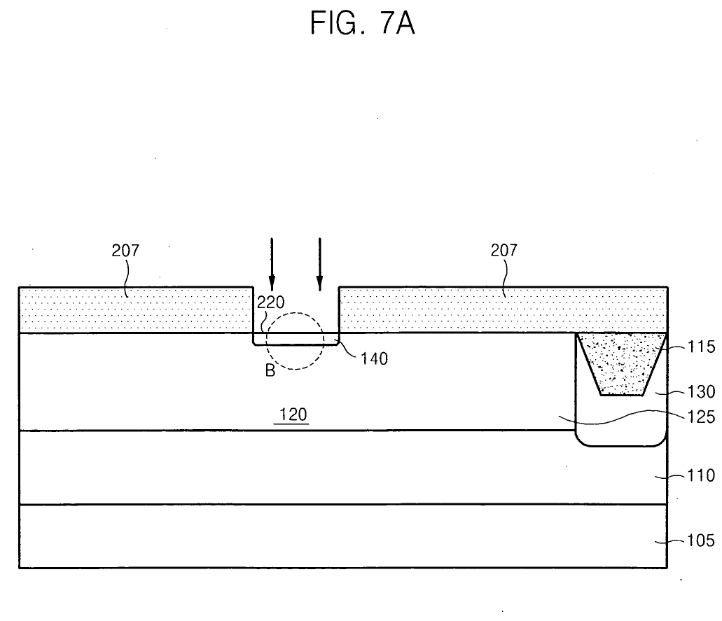

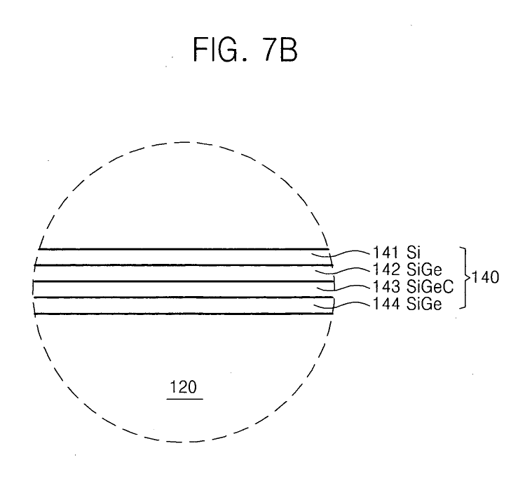

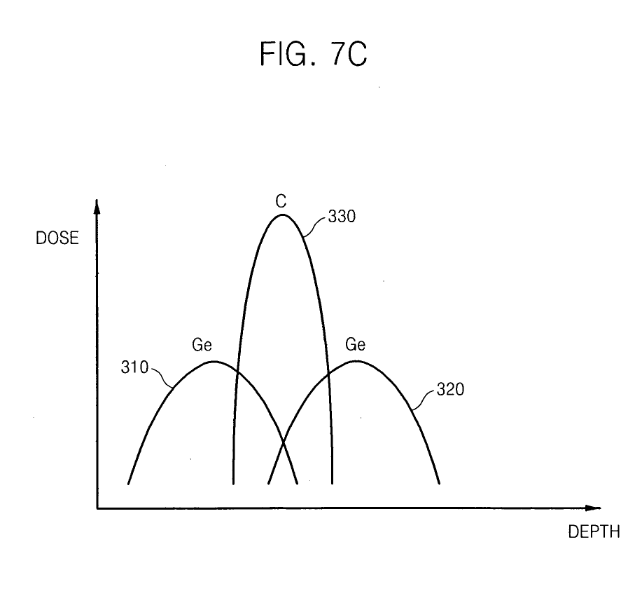

A method of fabricating the CMOS image sensor of FIGS. 3A, 3B, and 3C is now described with reference to FIGS. 4, 5, 6, 7A, 7B, 7C, 8, and 9. FIGS. 4, 5, 6, 7A, 7B, 8, and 9 show cross-sectional views during sequential steps for fabricating such a CMOS image sensor. FIG. 7C shows dopant profiles for forming the channel region 140 of the drive transistor Dx, according to an embodiment of the present invention. Each dopant profile is a graph of dopant concentration versus depth from the top surface of the silicon substrate 105.

Referring to FIG. 4, the deep P-well 110 is formed in the semiconductor substrate 105 by implanting a P-type dopant such as (B) or boron fluoride (BF₂) deep into the semiconductor substrate 105. Thereafter, the device isolation region 115 is formed using for example a shallow trench isolation (STI) process to define the active region 120 in the semiconductor substrate 105. Alternatively, a nitride/oxide localized oxidation of silicon (LOCOS) process may be used to form the device isolation region 115.

Next, the P-well 125 for forming the active region 120 is formed by implanting a P-type dopant into the semiconductor substrate 105. In addition, the channel stop region 130 contacting the deep P-well 110 may be formed below the device isolation region 115 by implanting P-type dopant for example.

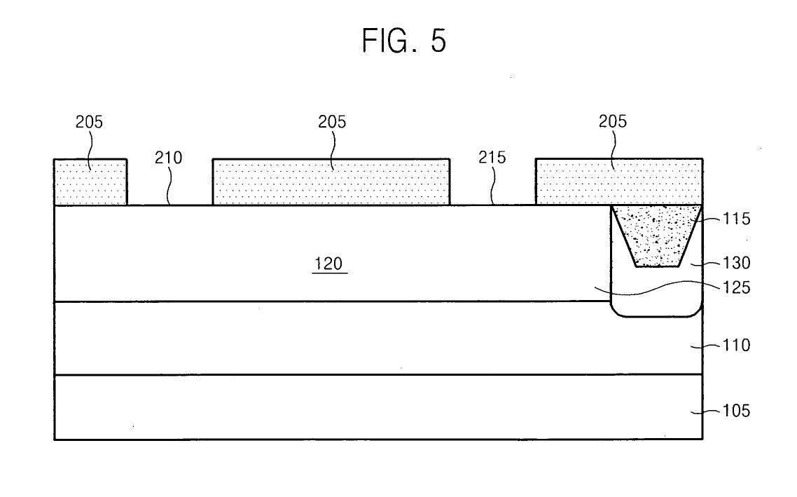

Thereafter referring to FIG. 5, a first implantation mask 205 is patterned to expose a region 210 of the active region 120 for forming a channel region of the reset transistor (158 in FIG. 3A). Also, a region 215 of the active region 120 is also exposed for forming a channel region of the select transistor (178 in FIG. 3A).

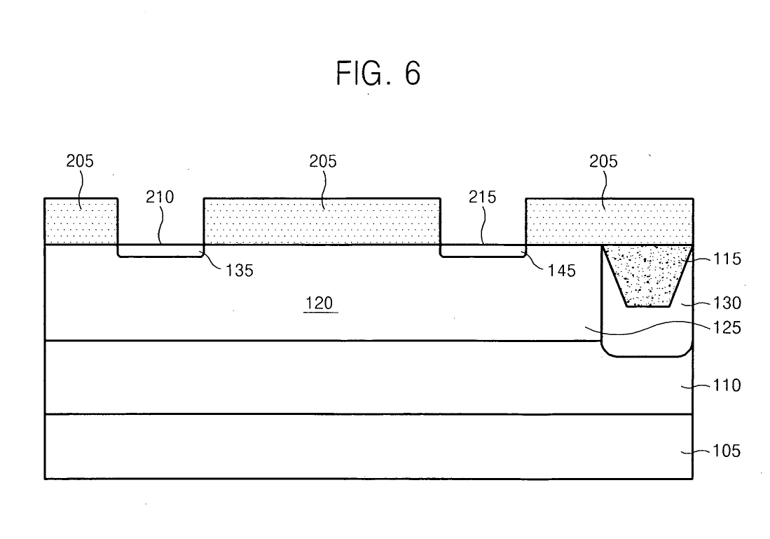

Subsequently referring to FIG. 6, a P-type dopant is implanted into the exposed regions 210 and 215 using the first implantation mask 205 to form the first impurity doped region 135 and the third impurity doped region 145 that are each P⁻-type conductivity. The first and third impurity doped regions 135 and 145 are formed to control the threshold voltages of the reset transistor 158 and the select transistor 178, respectively.

In addition, an N-type dopant may also be implanted below the P⁻-type regions such that each of the first and third impurity doped regions 135 and 145 has a stack structure with a respective N⁻-type impurity doped region formed below the respective P⁻-type impurity doped region. Here, the order for implanting the P-type dopant and the N-type dopant for forming the P⁻-type impurity regions and the N⁻-type impurity regions is not restricted to a particular order.

Thereafter referring to FIG. 7A, the first implantation mask 205 of FIG. 6 is removed, and a second implantation mask 207 is patterned on the semiconductor substrate 105 to expose a region 220 of the active region 120. Next, a plurality of dopants is implanted into the exposed region 220 to form the second impurity doped region 140 that forms a channel region of the drive transistor 168.

In detail, FIG. 7C shows a plurality of dopant profiles including a first dopant profile 310 for a germanium dopant implanted into the exposed region 220, a second dopant profile 320 for a germanium dopant implanted into the exposed region 220, and a third dopant profile 330 for a carbon dopant implanted into the exposed region 220. Each of the dopant profiles 310, 320, and 330 is a graph of the implantation dose of the respective dopant versus the depth from the top surface of the exposed region 220 of the active region 120.

The order for implantation of germanium and carbon for the dopant profiles 310, 320, and 330 is not restricted to any particular order. In addition, the implantation dose and depth are not particularly restricted and may be selected in various ranges according to desired device characteristics.

Thereafter, the semiconductor substrate 105 doped with the Ge and C dopants according to the dopant profiles 310, 320, and 330 is annealed at a temperature of from about 800 to about 1000° C. As a result, the second impurity doped region 140 has a stacked structure as illustrated in FIG. 7B.

Thus, a top silicon region 141 is formed toward the top surface of the semiconductor substrate. In addition, a first SiGe region 142 is formed below and abutting the top silicon layer 141 by reaction between silicon of the semiconductor substrate 105 and the germanium dopant. Furthermore, a SiGeC region 143 is formed below and abutting the first SiGe region 142 by reaction between the silicon of the semiconductor substrate 105 and the germanium and carbon dopants. Additionally, a second SiGe region 144 is formed below and abutting the SiGeC region 143 by reaction between the semiconductor substrate 105 and the germanium dopant.

Thus, note that the SiGeC region 143 is formed between the first and second SiGe regions 142 and 144. Furthermore, note that the doped regions 142, 143, and 144 are formed to be buried below the top silicon region 141 of the semiconductor substrate.

In this manner, the second impurity doped region 140 with the stacked structure of FIG. 7C has the energy bands of FIG. 3C in the channel region of the drive transistor Dx. Thus, mobility of electrons are increased therein for preventing charge loss due to charge trapping at the interface of the gate dielectric 160 and the semiconductor substrate 105 such that flicker noise in minimized. In one embodiment of the present invention, the second impurity doped region 140 is formed after the first and third impurity doped regions 135 and 145 are formed. However, the present invention may be practiced with different orders of forming such regions 135, 140, and 145.

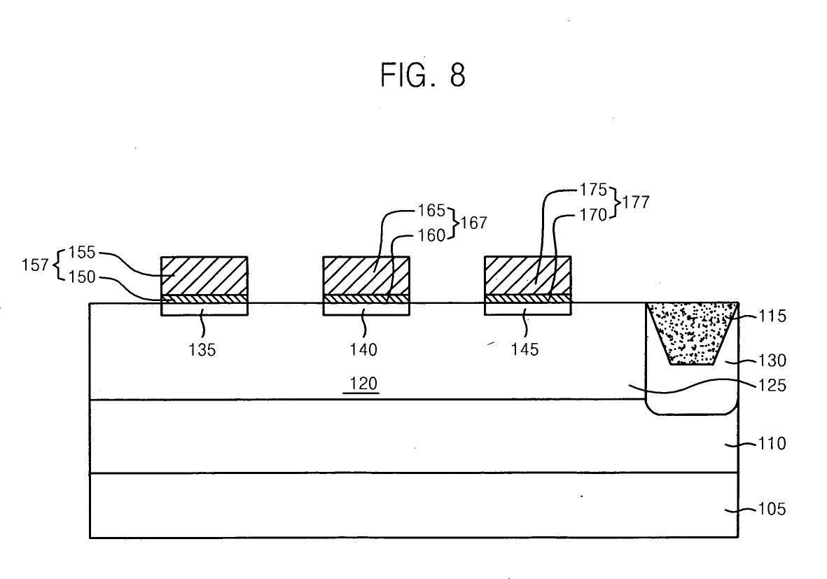

Subsequently referring to FIG. 8, the second implantation mask 207 of FIG. 7A is removed and a gate dielectric layer (not shown) and a gate electrode layer (not shown) are sequentially formed on the active region 120 of the semiconductor substrate 105. For example, the gate dielectric layer may be formed from thermal oxidation or may be formed by deposition of oxide or nitride using chemical vapor deposition (CVD). The gate electrode layer my be comprised of polysilicon, tungsten (W), titanium nitride (TiN), tantalum (Ta), tantalum nitride (TaN), or a combination thereof.

Thereafter, the reset gate 157, the drive gate 167, and the select gate 177 are patterned from such a gate dielectric layer and such a gate electrode layer over the regions 135, 140, and 145, respectively. The gate dielectric layer is patterned to form the gate dielectrics 150, 160, and 170 of the reset gate 157, the drive gate 167, and the select gate 177, respectively. The gate electrode layer is patterned to form the gate electrodes 155, 165, and 175 of the reset gate 157, the drive gate 167, and the select gate 177, respectively.

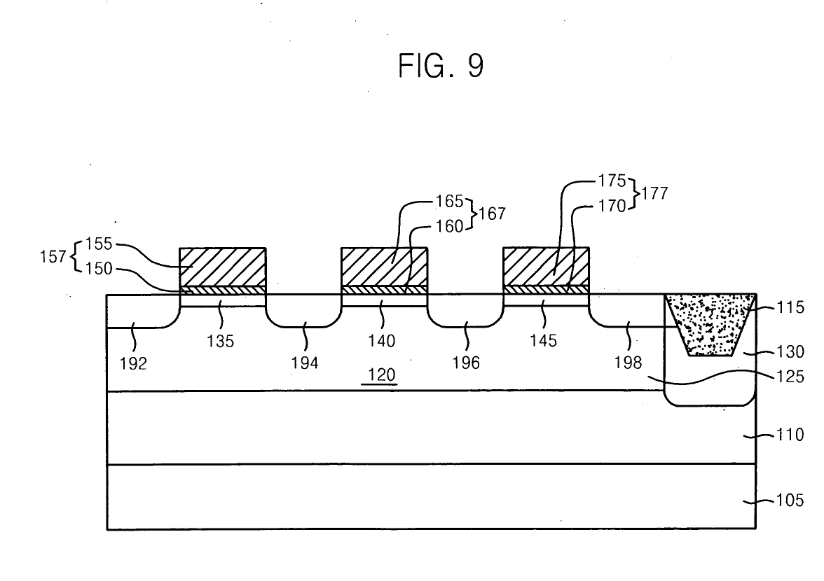

Subsequently referring to FIG. 9, an N-type dopant is implanted into exposed regions of the active region to form the N⁺-type source regions 192 and 196 and drain regions 194 and 198. In an alternative embodiment of the present invention, gate spacers (not shown) may be formed on sidewalls of the gates 157, 167, and 177 before formation of the source regions 192 and 196 and the drain regions 194 and 198. Thereafter, light receiving lenses (not shown) and metal interconnection (not shown) are formed using typical CMOS fabrication methods known to those skilled in the art, thereby completing the CMOS image sensor.

In the above-described embodiment of the present invention, the drive transistor Dx is described as having the stack structure with the multiple doped regions 141, 142, 143, and 144 of FIG. 7C. However, the present invention may also be practiced with any of the reset transistor Rx, the transfer transistor Tx, and the select transistor Sx also having such similar stacked structure of FIG. 7C in the respective channel region for increased electron mobility therein.

While the present invention has been shown and described with reference to exemplary embodiments thereof, it will be understood by those of ordinary skill in the art that various changes in form and detail may be made herein without departing from the spirit and scope of the present invention, as defined by the following claims.

The present invention is limited only as defined in the following claims and equivalents thereof.

What is claimed is:

1. An image sensor comprising:
a photo sensitive device; and
at least one transistor for converting charge accumulated by the photo sensitive device into an electrical signal,
wherein the at least one transistor includes a channel region comprised of a plurality of differently doped regions that generates a conduction band offset in the channel region.

2. The image sensor of claim 1, wherein the at least one transistor is a drive transistor having a gate dielectric and a gate electrode formed over the channel region that is buried in a semiconductor substrate.

3. The image sensor of claim 2, further comprising:
a floating diffusion node coupled to a gate of the drive transistor;
a transfer transistor coupled between the photo sensitive device and the floating diffusion node;
a select transistor coupled between the drive transistor and an output node; and
a reset transistor coupled between the floating diffusion node and a reset voltage source.

4. The image sensor of claim 3, wherein each of the transfer transistor, the select transistor, and the reset transistor has a respective channel comprised of a plurality of differently doped regions that generates a respective conduction band offset in the respective channel region.

5. The image sensor of claim 1, wherein the plurality of differently doped regions further generates a valence band offset in the channel region.

6. The image sensor of claim 5, wherein the valence band offset is formed at an interface of a silicon substrate and a region comprised of SiGe (silicon germanium).

7. The image sensor of claim 1, wherein the conduction band offset is formed at an interface of a region comprised of SiGe (silicon germanium) and another region comprised of SiGeC (silicon germanium carbon).

8. The image sensor of claim 1, wherein the plurality of differently doped regions includes first and second regions of SiGe (silicon germanium) and a region of SiGeC (silicon germanium carbon) formed between the first and second regions of SiGe.

9. The image sensor of claim 8, wherein the regions of SiGe and SiGeC are formed buried below a surface of a silicon substrate.

10. The image sensor of claim 1, wherein the plurality of differently doped regions includes:
a first region of SiGe (silicon germanium) having a first dopant profile of germanium implanted into a silicon substrate;
a second region of SiGe having a a second dopant profile of germanium implanted into the silicon substrate; and
a region of SiGeC (silicon germanium carbon) having a third dopant profile of germanium and carbon implanted into the silicon substrate and being disposed between the first and second regions of SiGe.

11. The image sensor of claim 1, wherein the image sensor is a CMOS (complementary metal oxide semiconductor) image sensor.

12. An image sensor comprising:
a photo sensitive device; and
at least one transistor for converting charge accumulated by the photo sensitive device into an electrical signal; and
means for generating a conduction band offset in a channel region of the at least one transistor.

13. The image sensor of claim 12, wherein the at least one transistor is a drive transistor having a gate dielectric and a gate electrode formed over the channel region that is buried in a semiconductor substrate.

14. The image sensor of claim 13, further comprising:
a floating diffusion node coupled to a gate of the drive transistor;
a transfer transistor coupled between the photo sensitive device and the floating diffusion node;
a select transistor coupled between the drive transistor and an output node; and
a reset transistor coupled between the floating diffusion node and a reset voltage source.

15. The image sensor of claim 14, wherein each of the transfer transistor, the select transistor, and the reset transistor has a respective channel comprised of a plurality of differently doped regions that generates a respective conduction band offset in the respective channel region.

16. The image sensor of claim 12, further comprising:
means for generating a valence band offset in the channel region.

17. The image sensor of claim 16, wherein the valence band offset is formed at an interface of a silicon substrate and a region comprised of SiGe (silicon germanium).

18. The image sensor of claim 12, wherein the conduction band offset is formed at an interface of a region comprised of SiGe (silicon germanium) and another region comprised of SiGeC (silicon germanium carbon).

19. The image sensor of claim 12, wherein the conduction band offset is generated from a plurality of differently doped regions including first and second regions of SiGe (silicon germanium) and a region of SiGeC (silicon germanium carbon) formed between the first and second regions of SiGe.

20. The image sensor of claim 19, wherein the regions of SiGe and SiGeC are formed buried below a surface of a silicon substrate.
